(19) United States
(12) Patent Application Publication
(10) Pub. No.: US 2011/0241125 A1
(43) Pub. Date: Oct. 6, 2011

(54) Power Semiconductor Device with Low Parasitic Metal and Package Resistance

(75) Inventors: William Edward Rader, III, Carrboro, NC (US); Satya Chinnusamy, San Jose, CA (US); Richard George Spicer, San Jose, CA (US)

(73) Assignee: SEMTECH CORPORATION, Morrisville, NC (US)

(21) Appl. No.: 12/750,743

(22) Filed: Mar. 31, 2010

(51) Int. Cl. H01L 23/52; H01L 21/60; H01L 23/495

(52) U.S. Cl. 257/401; 438/122; 257/676; 257/E21.509; 257/E23.141; 257/E23.031

(57) ABSTRACT

A power semiconductor device includes a semiconductor die with a power transistor on a semiconductor substrate, a plurality of wiring layers vertically spaced apart from one another and the transistor, and a plurality of conductive bumps on each wire of the wiring layer spaced farthest from the substrate. Each wire of the layer closest to the substrate is electrically connected to a terminal of the transistor. The wires of the layer spaced farthest from the substrate extend in generally parallel lines and are electrically connected to a terminal of the transistor through each underlying layer. An additional metal layer having a thickness of at least 50 μm is connected to the die so that contact regions of the additional metal layer are electrically connected to the bumps of the die.

### TECHNICAL FIELD

The present invention generally relates to power semiconductor devices, and more particularly relates to reducing parasitic metal and package resistance of power semiconductor devices.

### BACKGROUND

High current, low resistance MOSFETs (Metal Oxide Semiconductor Field Effect Transistors) and other types of power transistors were traditionally formed on separate silicon from the control circuitry which drives the transistors. As process capabilities improve over time, it is more common to place low resistance power transistors and the corresponding control circuitry on the same integrated circuit die. A major challenge in achieving good performance for a low resistance power transistor is to ensure that the parasitic resistance between the drain and source regions of the transistor to the pins of the package is relatively small compared to the channel resistance of the transistor. This is necessary in order to ensure good performance parameters of the device.

The parasitic resistance typically includes two main components. The first component is the resistance from the silicon drain and source regions of each power transistor to the top metal pads of the device, commonly referred to as ‘metal parasitic resistance’. The second component of the parasitic resistance is the resistance from the top metal pads of the integrated circuit device to the pins of the package, commonly referred to as ‘package parasitic resistance’.

The largest component of the metal parasitic resistance typically arises when the device current travels laterally from one side of the power device to the pads on the other side. As current builds up across the device, reliability issues arise, such as electromigration caused by a large amount of current traveling through thin pieces of metal. Current crowding can also occur in parts of the device with lower metal resistance, causing thermal hot spots in the device which can lead to subsequent damage at high current levels. In order to address these issues, semiconductor processes sometimes provide thick layers of metal and use copper metal instead of aluminum because copper has lower resistivity and better reliability when carrying large amounts of current. However, thicker metal can cause a larger metal pitch, making wire routing more difficult on other parts of the chip. Also, copper wiring increases manufacturing cost and complexity.

The dominant components of the package parasitic resistance are bond wire resistance and lead resistance, the bond wire resistance typically being larger. Bond wire resistance can be reduced by using multiple bond wires in parallel and thicker metal in the bond wires. However, both solutions increase cost. In addition, thicker bond wire metal requires a larger bond pad size and pitch on the control circuitry of the integrated circuit die.

### SUMMARY

According to an embodiment of a method for manufacturing a power semiconductor device, the method includes providing a semiconductor die with a first power transistor on a semiconductor substrate, a plurality of wiring layers vertically spaced apart from one another and the first power transistor and a plurality of conductive bumps on each wire of the layer spaced furthest from the substrate. Each wire of the wiring layer closest to the substrate is electrically connected to a terminal of the first power transistor. The wires of the wiring layer spaced furthest from the substrate extend in generally parallel lines and are electrically connected to a terminal of the first power transistor through each underlying wiring layer. An additional metal layer having a thickness of at least 50 μm is connected to the die so that contact regions of the additional metal layer are electrically connected to the plurality of conductive bumps of the die.

According to an embodiment of a power semiconductor device, the device includes a semiconductor die with a first power transistor on a semiconductor substrate, a plurality of wiring layers vertically spaced apart from one another and the first power transistor, and a plurality of conductive bumps on each wire of the wiring layer spaced farthest from the substrate. Each wire of the wiring layer closest to the substrate is connected to a terminal of the first power transistor. The wires of the wiring layer spaced farthest from the substrate extend in generally parallel lines and are electrically connected to a terminal of the first power transistor through each underlying wiring layer. The device further includes an additional metal layer having a thickness of at least 50 μm connected to the die so that contact regions of the additional metal layer are electrically connected to the plurality of conductive bumps of the die.

According to another embodiment of a power semiconductor device, the device includes a semiconductor die with a first power transistor on a semiconductor substrate, a plurality of wiring layers vertically spaced apart from one another and the first power transistor, and a plurality of conductive bumps on each wire of the wiring layer spaced farthest from the substrate. Each wire of the wiring layer closest to the substrate is electrically connected to a terminal of the first power transistor. The wires of the wiring layer spaced farthest from the substrate have a thickness of at least 4 μm, extend in generally parallel lines and are electrically connected to a terminal of the first power transistor through each underlying wiring layer. The device further includes a lead frame including a first conductive region connected to the plurality of conductive bumps electrically connected to a source terminal of the first power transistor, and a second conductive region connected to the plurality of conductive bumps electrically connected to a drain terminal of the first power transistor, the first and second conductive regions of the lead frame having a thickness of at least 50 μm.

Of course, the present invention is not limited to the above features and advantages. Those skilled in the art will recognize additional features and advantages upon reading the following detailed description, and upon viewing the accompanying drawings.

### BRIEF DESCRIPTION OF THE DRAWINGS

FIG. 1 illustrates a top-down plan view of an embodiment of a power semiconductor die including a redistribution wiring layer.

FIG. 2 illustrates a circuit diagram of an embodiment of power transistors and corresponding control circuitry included in the power semiconductor die of FIG. 1.

FIG. 3 illustrates a top-down plan view of an embodiment of a power semiconductor device including a lead frame attached to the power semiconductor die of FIG. 1.

FIG. 4 illustrates the lead frame of FIG. 3 attached to the redistribution wiring layer of the power semiconductor die of FIG. 1.

FIGS. 5-14 illustrate partial top-down plan views of the different wiring layers included in the power semiconductor die of FIG. 1.

### DETAILED DESCRIPTION

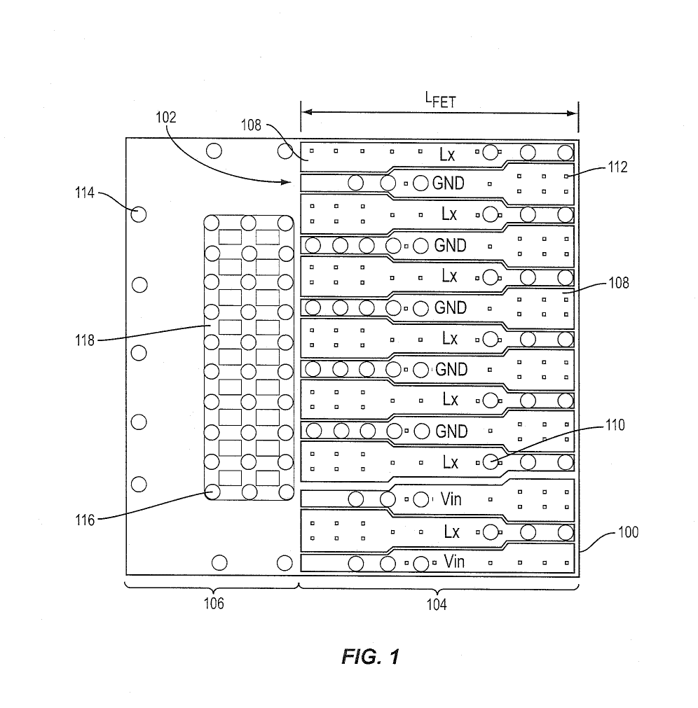

FIG. 1 illustrates a top-down plan view of a power semiconductor die 100 including an uppermost wiring layer 102 which is referred to herein as a redistribution layer. The semiconductor die 100 also includes one or more additional wiring layers formed below the redistribution layer 102 and above a semiconductor substrate of the die 100, each of which are out-of-view in FIG. 1. One or more power transistors are formed on a first region 104 of the substrate and a corresponding control circuit is formed on a second region 106 of the substrate for controlling operation of the power transistor(s), the power transistor(s) and control circuit also being out-of-view in FIG. 1.

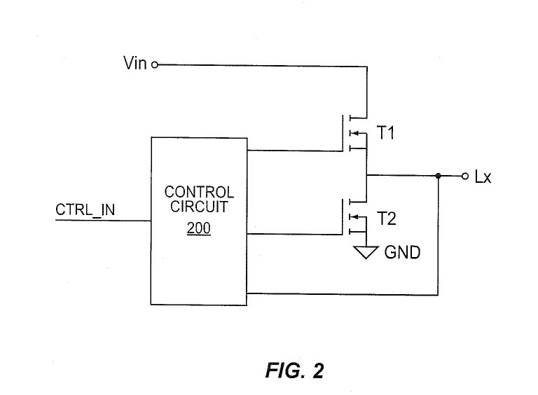

FIG. 2 illustrates a circuit diagram of an embodiment of a pair of power transistors T1 and T2 such as MOSFETs or other type of transistor formed on the first region 104 of the semiconductor substrate and a control circuit 200 formed on the second region 106 of the substrate. The control circuit 200 controls operation of T1 and T2. The drain terminal of T1 is connected to an input node labeled Vin. The source terminal of T1 is coupled to the drain terminal of T2 to form a common node which is also an output node and labeled Lx in FIG. 2. The source terminal of T2 is connected to ground (GND). The control circuit 200 controls the respective gates of T1 and T2 responsive to one or more control signals (CTRL_IN) input to the control circuit 200 and the level of the output node Lx. Of course, any number and type of power transistors and corresponding control circuitry can be formed on the different regions 104, 106 of the substrate.

Returning to FIG. 1, each layer of wiring formed above the semiconductor substrate provides electrical connections to the power transistor(s) and control circuit of the die 100. The wiring layers are vertically spaced apart from one another and the substrate. Each wire of the layer arranged closest to the substrate is electrically connected to a terminal of a power transistor such as the source, drain, gate or well. For example, some of the wires included in the lowermost wiring layer may be connected to the input node labeled Vin in FIG. 2. Other ones of the wires may be connected to the common/output node labeled Lx, and still other ones of the wires may be connected to the ground node labeled GND. Electrical connections to the corresponding control circuitry are provided by different wiring layers arranged over the region 106 of the substrate on which the control circuitry is formed.

Each wire of the wiring layers arranged above the lowermost layer is electrically connected to a plurality of the wires of the immediately underlying layer so that the number of wires in each layer electrically connected to the source, drain and/or other terminals of a power transistor of the die 100 decreases as a function of vertical distance from the substrate. As such, there are fewer wires of greater width in the layers arranged farthese from the substrate compared to the layers arranged closer to the substrate. The redistribution layer 102 is relatively thick compared to the underlying metals layers. In one embodiment, the redistribution layer 102 is at least 4 μm thick, and is preferably 8 μm thick or greater. Therefore, the redistribution layer 102 has a much lower sheet resistance than the underlying metals layers and ensures a very low resistance current flow path in the uppermost wiring layer of the die 100. According to an embodiment, the redistribution layer 102 is made of a first material having a relatively low resistance such as copper, and the underlying metals layers are made of a different material having a higher resistance such as aluminum.

In each case, bumps 110 are formed on each wire 108 of the redistribution layer 102 for electrically connecting each power transistor and control circuit formed on the substrate to a package lead frame or directly to a circuit board or other type of assembly to which the power semiconductor die 100 is to be attached, neither of which are shown in FIG. 1. In some embodiments, the redistribution layer 102 is made of copper and is approximately 8 μm thick. Broadly, the redistribution layer 102 can have any desired thickness and be made of any suitable conductive material. The wires 108 of the redistribution layer 102 extend in generally parallel lines and are electrically connected to a terminal of a power transistor included in the die 100 through each underlying wiring layer as described in more detail later herein. According to an embodiment, the wires 108 of the redistribution layer 102 extend generally parallel to one another over at least 90% of the length (L_{FET}) of a power transistor formed on the substrate, but do not extend over the region 106 of the substrate on which the corresponding control circuit is formed. For other embodiments, the redistribution layer wires 108 extend over regions of the control circuitry 200 in order to reduce the resistance to the lead frame 301 described later herein.

Each wire 108 of the redistribution layer 102 is relatively wide and straight and functions as a bus for providing a low resistance lateral current path between each underlying wiring layer and the lead frame or circuit board to which the power semiconductor die 100 is to be attached. The width of the redistribution layer wires 108 can vary over the length of the wires 108 as shown in FIG. 1, as can the wires of the other metal layers. Openings 112 can be formed in the wires 108 of the redistribution layer 102 and filed with an adhesive insulating material for reducing delamination, particularly when the redistribution layer 102 is made of copper. The redistribution layer 102 has very low resistance because of the relatively large wire width and the way in which the wires 108 of the redistribution layer 102 extend in parallel, providing a low resistance path for lateral current flow from each underlying metal layer to the lead frame or circuit board to which the power semiconductor die 100 is to be attached.

The bumps 110 formed on the wires 108 of the redistribution layer 102 can be made in accordance with any type of conventional bump formation technique. In one embodiment, the bumps 110 are copper pillar bumps. Contact between the redistribution layer 102 and the lead frame or circuit board to which the power semiconductor die 100 is to be attached can be made by the copper pillar bumps with a solder cap which can be any type of plated form of solder material or solder spheres.

Several of the bumps 110 may be electrically connected in parallel from the redistribution layer 102 to the lead frame or circuit board to which the power semiconductor die 100 is to be attached, reducing overall resistance of the bumps 110 and reducing the resistance for current flowing laterally through the redistribution layer 102. Additional electrically conductive terminals 114 provide points of electrical connection between the control circuitry of the power semiconductor die 100 and the lead frame or circuit board to which the power semiconductor die 100 is to be attached. Optional thermally conductive bumps 116 can be arranged over the region 106 of the die 100 where the control circuit is formed. The thermal bumps 116 can be electrically interconnected with metal wiring 118 and are electrically insulated from the control circuit and each power transistor of the die 100. The thermal bumps 116 are laterally spaced apart from the wires 108 of the redistribution layer 102 and connected to the lead frame or circuit board to which the die 100 is to be attached for increasing heat dissipation. The thermal bumps 116 carry no current, but reduce the thermal resistance from the die 100 to the lead frame or circuit board to which the die 100 is to be attached.

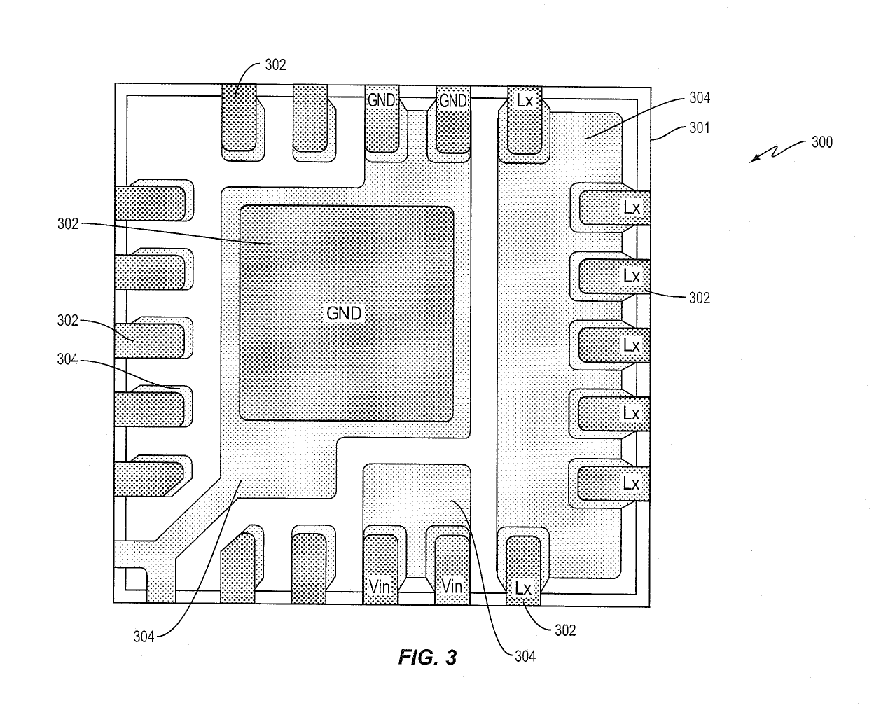

FIG. 3 illustrates an embodiment of a power semiconductor device 300 including a lead frame 301 for attaching to the redistribution layer 102 of the power semiconductor die 100. The lead frame 301 includes leads 302 and contact regions 304 such as metal plates or the like connected to the leads 302. The contact regions 304 connect to the wires 108 of the redistribution layer 102 of the die 100. In one embodiment, the contact regions 304 of the lead frame 301 are at least 50 μm thick, and preferably at least 100 μm thick. A first set of the pads 302 and a first one of the contact regions 304 of the lead frame 301 correspond to the ground terminal of a power transistor included in the die 100 and are correspondingly labeled GND. A second set of the pads 302 and a second one of the contact regions 304 correspond to the input terminal of the power transistor and are correspondingly labeled Vin. A third set of the pads 302 and a third one of the contact regions 304 correspond to the common node/output terminal of the power transistor and are correspondingly labeled Lx. In one embodiment, each of the two contact regions 304 for the drain and the source terminal of each power device cover greater than ¼ of each power MOSFET. Remaining ones of the pads 302 and contact regions 304 correspond to control signal inputs (CTRL_IN) provided to the corresponding control circuit included in the die 100.

According to an embodiment, the contact regions 304 of the lead frame 301 for the transistor source and drain connections directly under the redistribution layer 102 are relatively thick copper buses. If the copper buses of the lead frame 301 cover most of the area of the power transistors included in the die 100, the buses provide a near zero resistance path to the pins of the corresponding package which is not shown in FIG. 3. Multiple lead frame buses can be provided so that multiple separate power transistors can be placed on the same die 100. The redistribution layer 102 in conjunction with the lead frame 301 provides more than one order of magnitude reduction in resistance when compared to traditional packaging techniques, and dramatically relieves current crowding in the metal layers and within the power transistors since the parasitic resistance from any point within the die 100 is usually much less than the channel resistance of the power transistor(s). Also, the thermal resistance from the substrate of the power semiconductor die 100 to the lead frame 301 is significantly reduced for a number of reasons. First, relatively wide wiring layers are used from the substrate to the lead frame 301. Also, the lead frame 301 provides relatively thick metal directly under the power transistors of the die 100 to further reduce resistance. The thermal resistance of metal is significantly lower than that of a semiconductor material such as silicon and the semiconductor material of the power transistors has the most power dissipation and therefore generates the most heat. Furthermore, the control portions of the die 100, where there is no or limited need for bumps for electrical connections can use the thermal bumps 116 as explained above to connect the contact regions 304 of the lead frame 301 to the redistribution layer 102, allowing for reduced thermal resistance. The large internal GND lead 302 along with the multiple external leads 302 for GND, Lx and Vin, provide a path to the circuit board that is low in both electrical and thermal resistance.

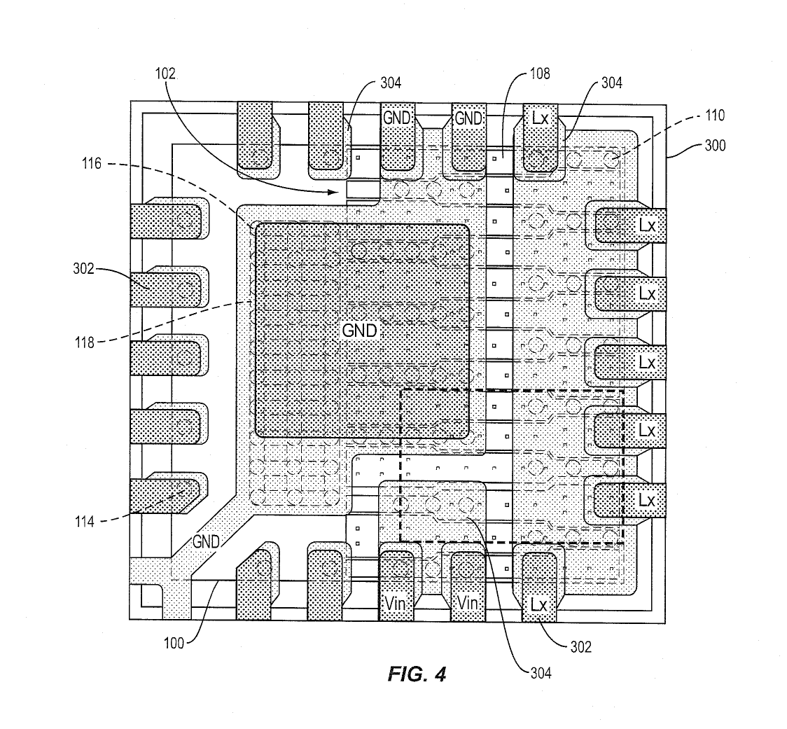

FIG. 4 shows the lead frame 301 placed on the power semiconductor die 100. The contact regions 304 of the lead frame 301 are connected to the bumps 110 formed on the wires 108 of the redistribution layer 102. In each case, several of the bumps 110 are electrically connected in parallel from each wire 108 of the redistribution layer 102 to the corresponding contact region 304 of the lead frame 301. For example, each wire 108 electrically connected to the ground terminal (GND) of a power transistor included in the die 100 has three or five copper pillar bumps 110 connected to the corresponding contact region 304 of the lead frame 301. Each wire 108 electrically connected to the input terminal (Vin) of the power transistor has three copper pillar bumps 110 connected to the corresponding contact region 304 of the lead frame 301 and each wire 108 electrically connected to the common node/output terminal (Lx) of the power transistor has three copper pillar bumps 110 connected to the corresponding contact region 304 of the lead frame 301. Of course, more or less of the bumps 110 may be provided for connecting each wire 108 of the redistribution layer 102 to the corresponding contact region 304 of the lead frame 301. Also, the thermally conductive bumps 116 formed over the corresponding control circuit are connected to the contact region 304 of the lead frame 301 which is electrically connected to the ground terminal (GND) of the power transistor for reducing thermal resistance of the die 100. FIGS. 3 and 4 show a single contact region 304 of the lead frame 301 for the source terminal of each power transistor and a single contact region 304 of the lead frame 302 for the drain terminal of each power transistor, but more than one contact region 304 can be used for connecting to either the source and/or drain terminals.

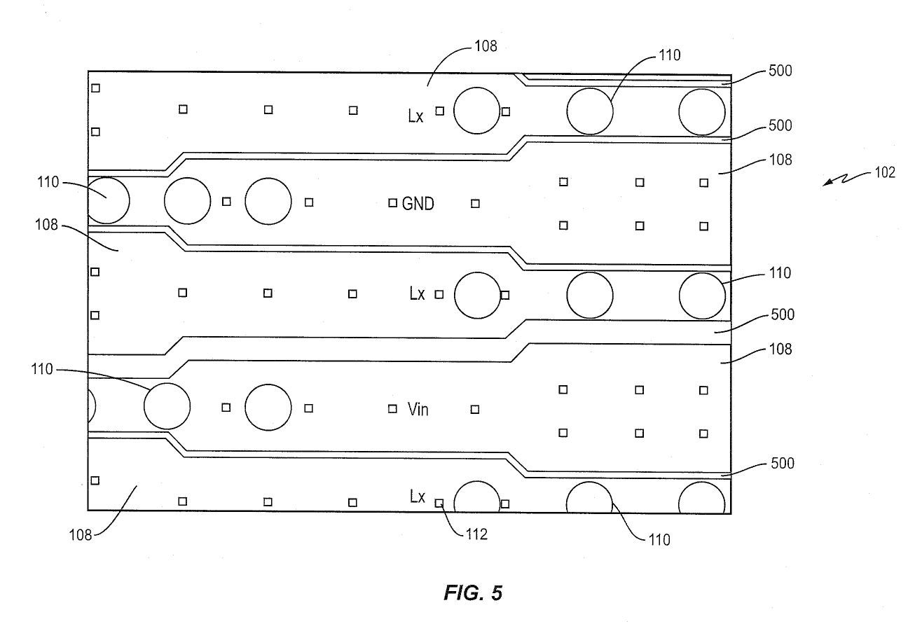

FIG. 5 illustrates the top part of the redistribution layer 102 in the region indicated by the dashed box shown in FIG. 4. Several of the bumps 110 are formed on the top of each redistribution layer wire 108. The redistribution layer wires 108 extend generally parallel to one another and are laterally spaced apart from each other by an insulating material 500. The width of the redistribution layer wires 108 may vary over the length of the wires 108 as shown in FIG. 5.

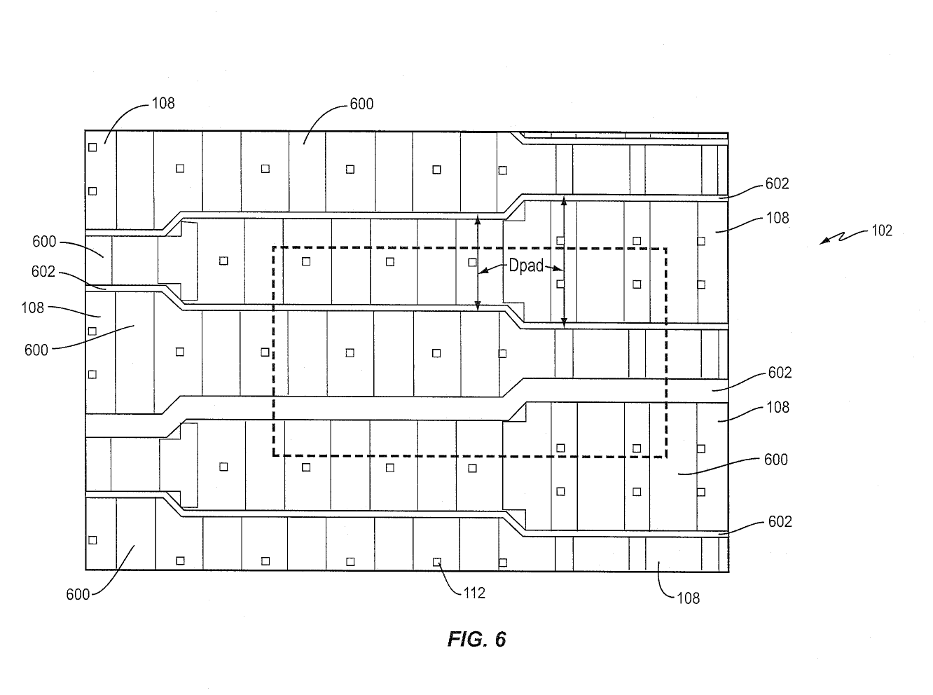

FIG. 6 illustrates the bottom part of the portion of the redistribution layer 102 shown in FIG. 5. In one embodiment, the die 100 is initially fabricated without the redistribution layer 102. According to this embodiment, contact pads 600 are formed on each wire of the layer currently spaced farthese from the substrate, i.e. the wiring layer just below the redistribution layer 102. A passivation layer 602 is formed over the wiring layer and the contact pads 600. Openings are subsequently formed in the passivation layer 602 to expose the contact pads 600. The redistribution wiring layer 102 is formed on the passivation layer 602 after the openings are formed in the passivation layer 602 so that the redistribution layer wires 108 are electrically connected to a terminal of a power transistor through the contact pads 600 and each underlying wire layer. Accordingly, the metal layers of the power semiconductor die 100 except for the redistribution layer 102 can be fabricated using conventional semiconductor processes that do not include thick copper metal layers. In one embodiment, the distance (D_{PAD}) between contact pads 600 of adjacent wires 108 connected to the same transistor terminal is between 200 μm and 300 um in order to set the lateral distance that current needs to flow in the metal layer immediately below the redistribution layer 102. Alternatively, fabrication of the die 100 includes the redistribution layer 102 and conductive vias are used instead of the contact pads 602 for connecting the redistribution layer wires 108 to the immediately underlying wiring layer.

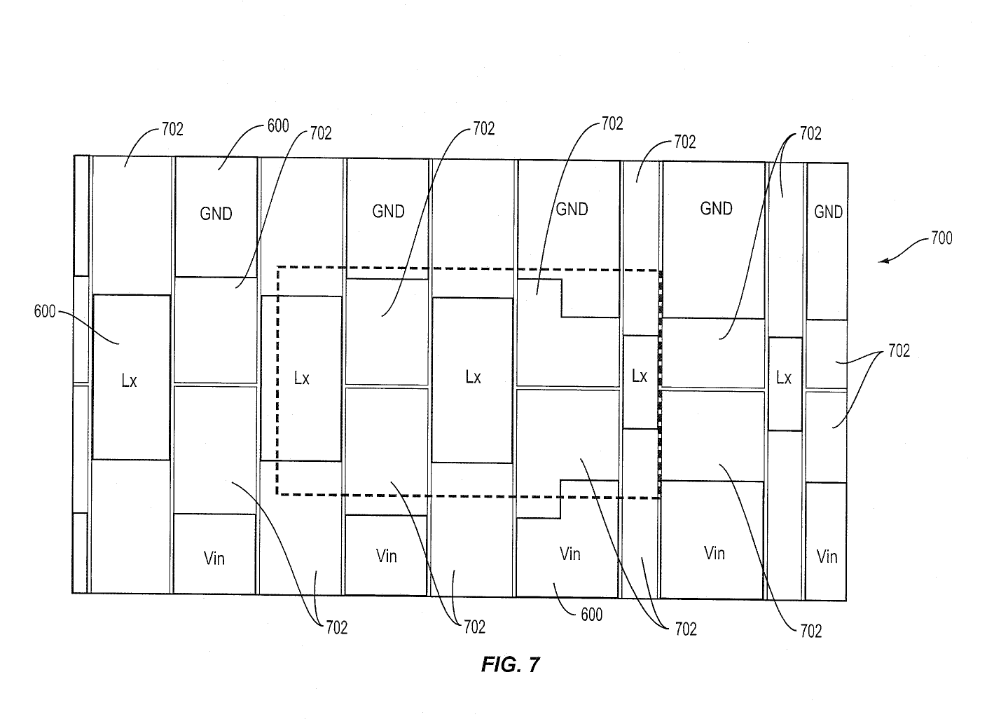

FIG. 7 illustrates the top part of the wiring layer 700 immediately below the redistribution layer 102 in the region indicated by the dashed box shown in FIG. 6. Comparing FIGS. 6 and 7, it can be seen that the redistribution layer 102 has fewer wires of greater width compared to the immediately underlying wiring layer 700 in the same region of the die 100. Each wire 108 of the redistribution layer 102 is electrically connected to several wires 702 of the wiring layer 700 immediately below the redistribution layer 102 through the contact pads 600 or conductive vias as described above.

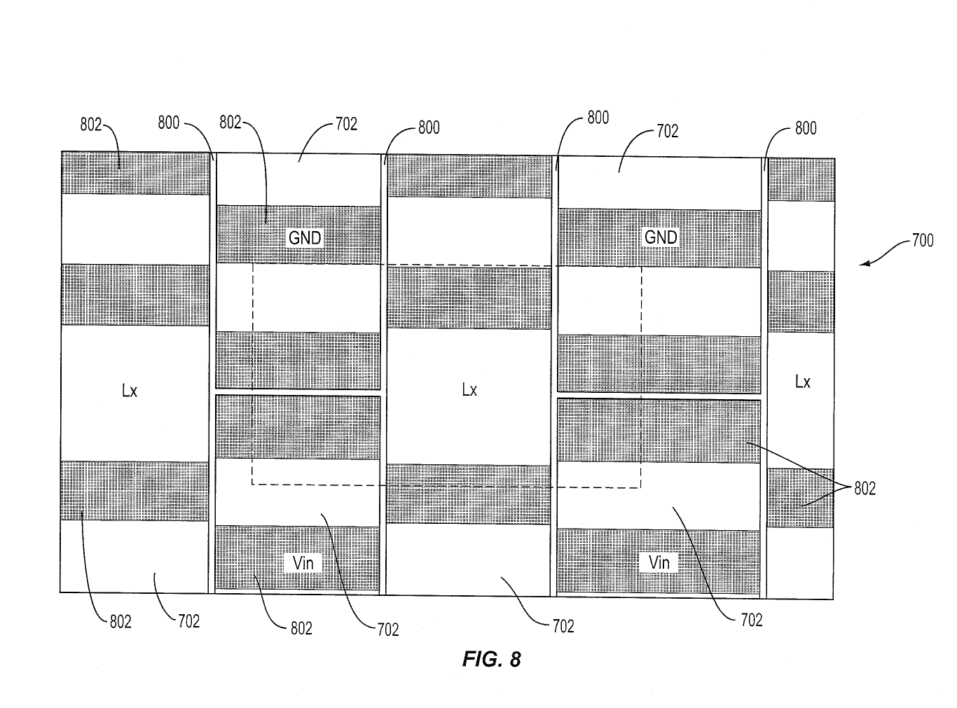

FIG. 8 illustrates the bottom part of the wiring layer 700 shown in FIG. 7 in the region indicated by the dashed box shown in FIG. 7. The metal wires 702 in this layer 700 extend in the opposite direction of the redistribution layer wires 108 and are laterally spaced apart from each other by an insulating material 800. Each wire 702 in this layer 700 is electrically connected to several wires of the immediately underlying wiring layer through several conductive vias 802.

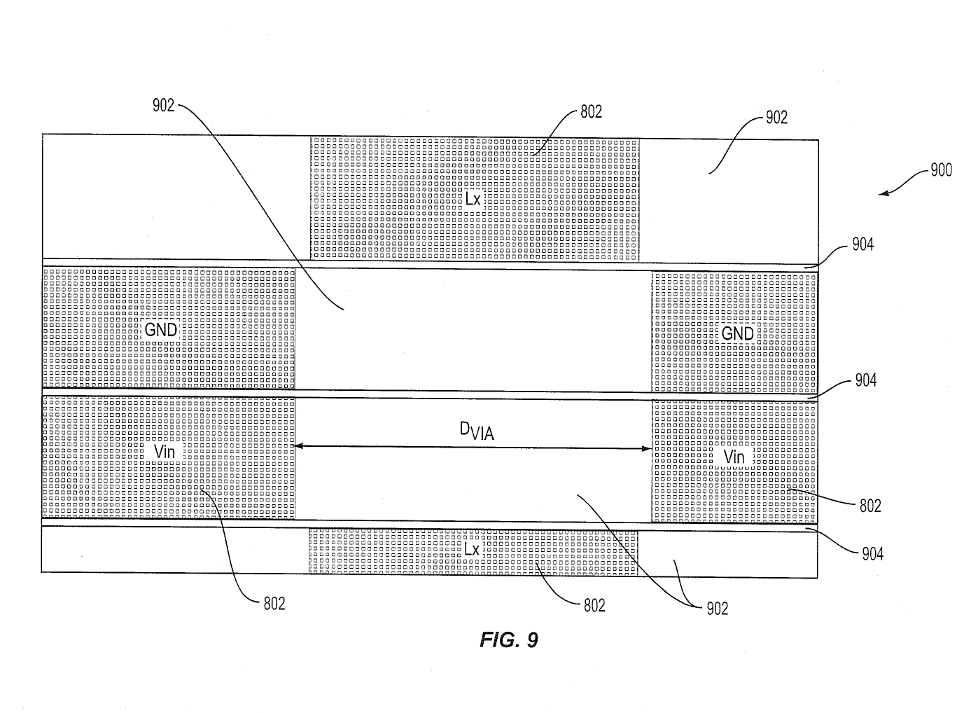

FIG. 9 illustrates the top part of the wiring layer 900 immediately below the wiring layer 700 shown in FIGS. 7 and 8 in the region indicated by the dashed box shown in FIG. 8. The metal wires 902 in this layer 900 extend in the opposite direction of the wires 702 in the immediately overlying layer 700 and are laterally spaced apart from each other by an insulating material 904. In one embodiment, the lateral distance (D_{VIA}) between adjacent vias 802 connecting one wire of the metal layer 900 to the overlying metal layer 700 is less than 100 μm, and preferably about 80 μm.

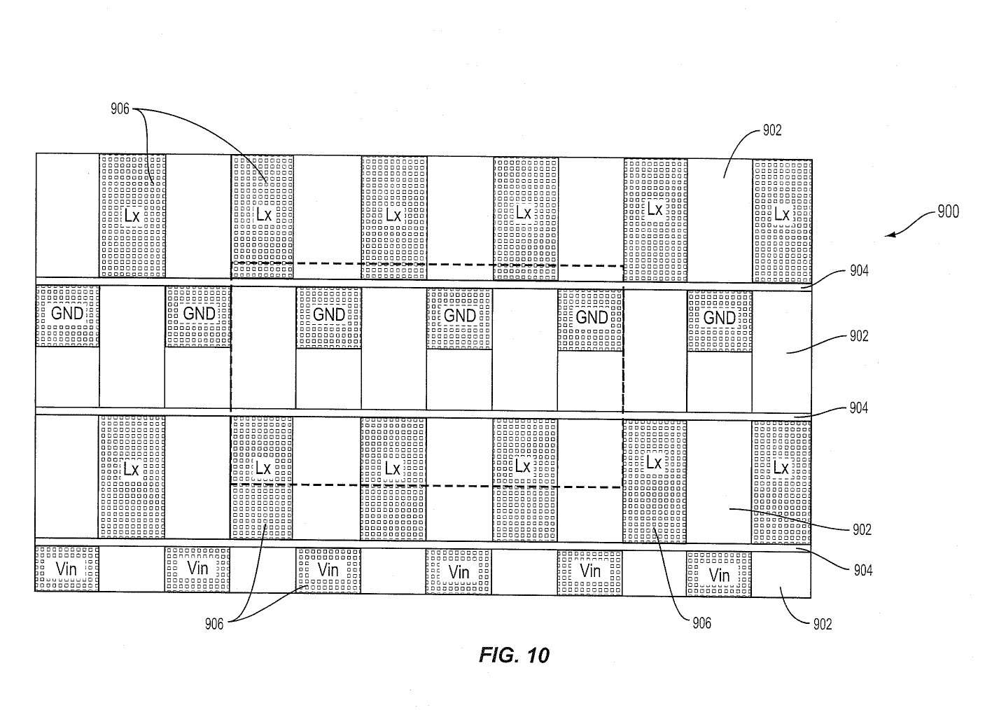

FIG. 10 illustrates the bottom part of the wiring layer 900 shown in FIG. 9. Each wire 902 in this layer 900 is electrically connected to several wires of the immediately underlying wiring layer through several conductive vias 906.

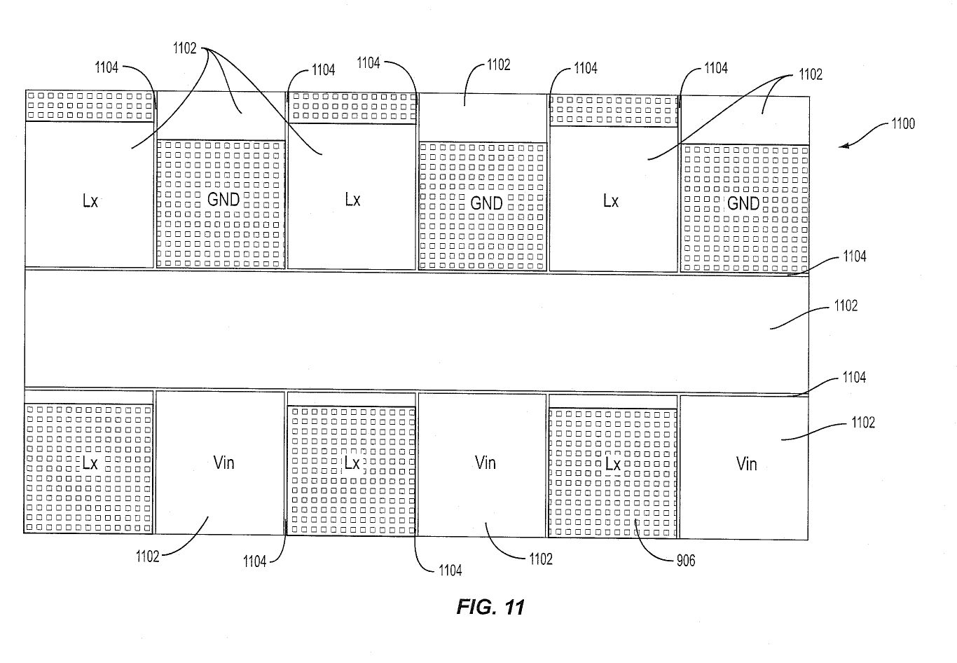

FIG. 11 illustrates the top part of the wiring layer 1100 immediately below the wiring layer 900 shown in FIGS. 9 and 10 in the region indicated by the dashed box shown in FIG. 10. The metal wires 1102 in this layer 1100 extend in the opposite direction of the wires 902 in the immediately overlying layer 900 and are laterally spaced apart from each other by an insulating material 1104.

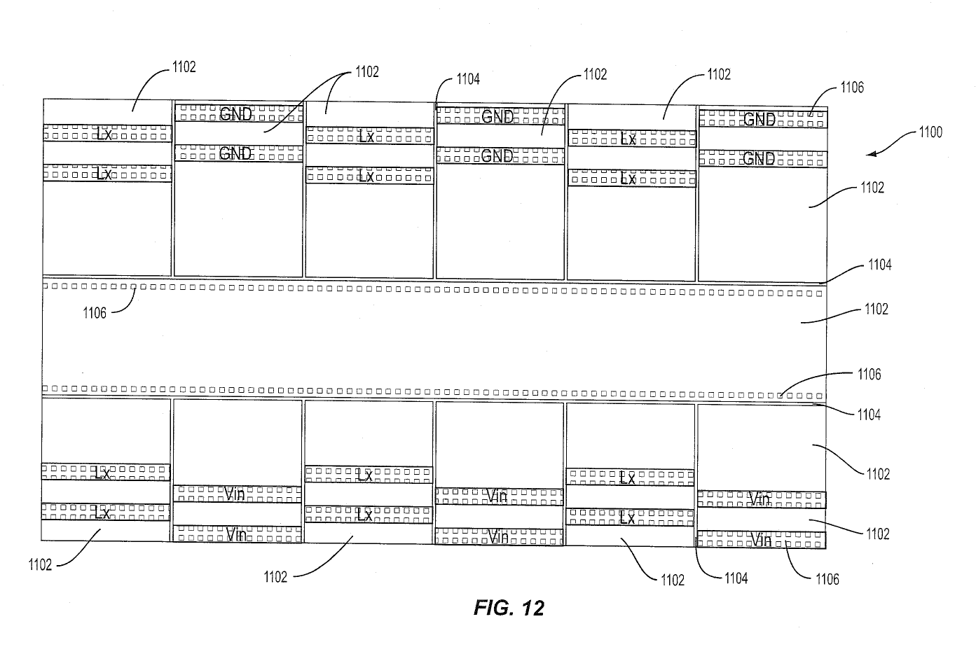

FIG. 12 illustrates the bottom part of the wiring layer 1100 shown in FIG. 11. Each wire 1102 in this layer 1100 is electrically connected to several wires of the immediately underlying wiring layer through several conductive vias 1106.

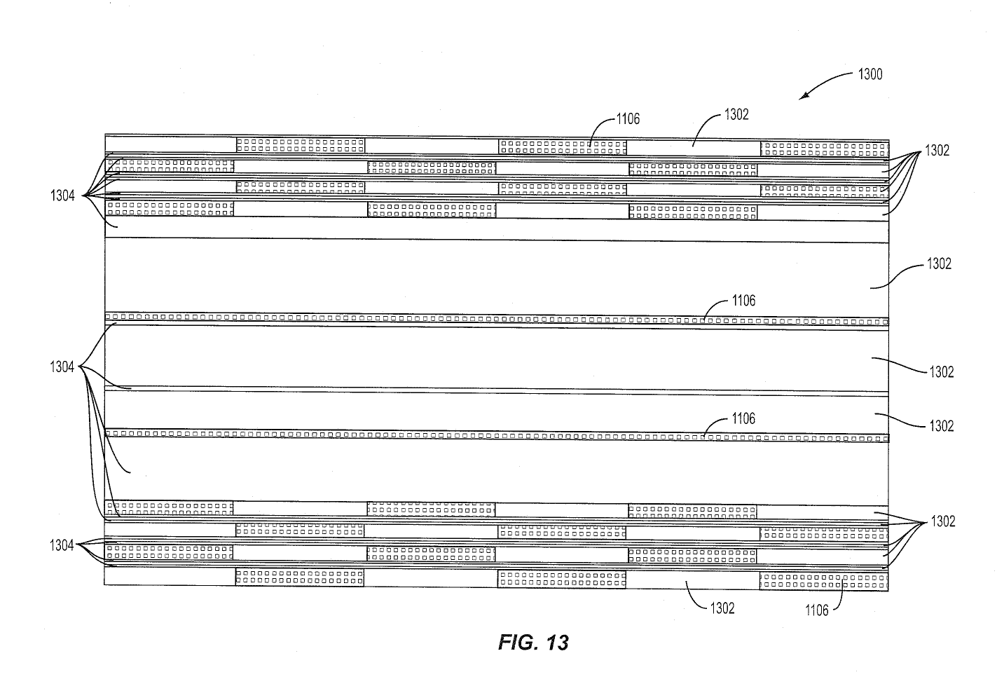

FIG. 13 illustrates the top part of the wiring layer 1300 immediately below the wiring layer 1100 shown in FIGS. 11 and 12 in the region indicated by the dashed box shown in FIG. 10. The metal wires 1302 in this layer 1300 extend in the opposite direction of the wires 1102 in the immediately overlying layer 1100 and are laterally spaced apart from each other by an insulating material 1304.

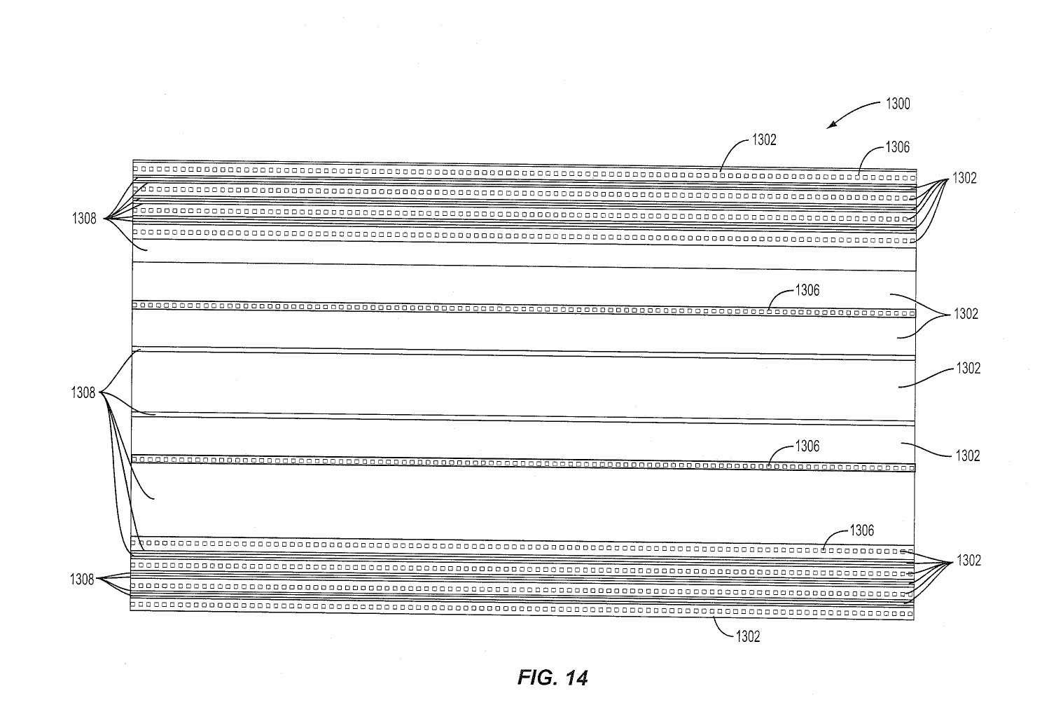

FIG. 14 illustrates the bottom part of the wiring layer 1300 shown in FIG. 13. Each wire 1302 in this layer 1300 is electrically connected to several regions of a power transistor formed on the substrate of the die 100 through several conductive contacts 1306. For example, one of the wires 1302 is electrically connected to several transistor regions corresponding to the ground terminal (GND) shown in FIG. 2 through several of the conductive contacts 1306. Another one of the wires 1302 is electrically connected to several transistor regions corresponding to the input terminal (Vin) shown in FIG. 2 through different ones of the conductive contacts 1306. Still another one of the wires 1302 is electrically connected to several transistor regions corresponding to the common node/output terminal (Lx) shown in FIG. 2 through yet other ones of the conductive contacts 1306. Other electrical connections are possible depending on the type and layout of power transistor(s) included in the die 100. The wiring layer 1300 closest to the substrate is separated from the substrate by an insulating material 1308 to ensure proper operation of the power semiconductor die 100, and thus the substrate is out-of-view. In FIGS. 3-14, the wires of each underlying metal layer are shown perpendicular to the wires of the immediately overlying layer. However, depending on the combination of available metal layers, other variations are possible where some metal layers may be parallel to the metal layer immediately above them in order to reduce the total parasitic resistance.

With the above range of variations and applications in mind, it should be understood that the present invention is not limited by the foregoing description, nor is it limited by the accompanying drawings. Instead, the present invention is limited only by the following claims, and their legal equivalents.

What is claimed is:

1. A method of manufacturing a power semiconductor device, comprising:
providing a semiconductor die with a first power transistor on a semiconductor substrate, a plurality of wiring layers vertically spaced apart from one another and the first power transistor, and a plurality of conductive bumps on each wire of the layer spaced farthest from the substrate, each wire of the wiring layer closest to the substrate being electrically connected to a terminal of the first power transistor, the wires of the wiring layer spaced farthest from the substrate extending in generally parallel lines and being electrically connected to a terminal of the first power transistor through each underlying wiring layers; and
connecting an additional metal layer having a thickness of at least 50 μm to the die so that contact regions of the additional metal layer are electrically connected to the plurality of conductive bumps of the die.

2. The method of claim 1, wherein the wires of the wiring layer of the die spaced farthest from the substrate extend in generally parallel lines over at least 90% of the first power transistor.

3. The method of claim 1, wherein the semiconductor die further includes a second power transistor on the substrate and a source terminal of the second power transistor is electrically connected to a drain terminal of the first power transistor to form a common node.

4. The method of claim 3, wherein each wire of the wiring layer of the die closest to the substrate is electrically connected to a terminal of the first or second power transistor, and the wires of the wiring layer of the die spaced farthest from the substrate are electrically connected to a terminal of the first or second power transistor through each underlying wiring layer.

5. The method of claim 1, further comprising:
connecting a first one of the contact regions of the additional metal layer, which covers at least ¼ of the first power transistor, to the plurality of conductive bumps electrically connected to a source terminal of the first power transistor; and
connecting a second one of the contact regions of the additional metal layer, which covers at least ¼ of the first power transistor, to the plurality of conductive bumps electrically connected to a drain terminal of the first power transistor.

6. The method of claim 5, wherein the semiconductor die further includes a control circuit on a region of the semiconductor substrate spaced laterally apart from the first power transistor, the control circuit being operable to control operation of the first power transistor.

7. The method of claim 6, further comprising forming a plurality of thermally conductive bumps above the region of the semiconductor substrate on which the control circuit is formed, the plurality of thermally conductive bumps being electrically insulated from the control circuit and the first power transistor, laterally spaced apart from the wiring layer of the die spaced farthest from the substrate and connected to one of the contact regions of the additional metal layer for increasing heat dissipation.

8. The method of claim 1, comprising:
prior to forming the wiring layer of the die spaced farthest from the substrate, forming a plurality of contact pads on each wire of the wiring layer of the die currently spaced farthest from the substrate and a passivation layer over the wiring layer and the plurality of contact pads;
subsequently forming openings in the passivation layer to expose the plurality of contact pads; and
forming the wiring layer of the die spaced farthest from the substrate on the passivation layer after the openings in the passivation layer are formed so that the wires of the wiring layer spaced farthest from the substrate are electrically connected to a terminal of the first power transistor through the plurality of contact pads and each underlying wiring layer.

9. The method of claim 1, comprising:
forming a plurality of openings in the wires of the wiring layer of the die spaced farthest from the substrate; and
filling the plurality of openings with an adhesive insulating material.

10. A power semiconductor device, comprising:
a semiconductor die with a first power transistor on a semiconductor substrate, a plurality of wiring layers vertically spaced apart from one another and the first power transistor, and a plurality of conductive bumps on each wire of the wiring layer spaced farthest from the substrate, each wire of the wiring layer closest to the substrate being electrically connected to a terminal of the first power transistor, the wires of the wiring layer spaced farthest from the substrate extending in generally parallel lines and being electrically connected to a terminal of the first power transistor through each underlying wiring layer; and
an additional metal layer having a thickness of at least 50 μm connected to the die so that contact regions of the additional metal layer are electrically connected to the plurality of conductive bumps of the die.

11. The power semiconductor device of claim 10, wherein the wires of the wiring layer of the die spaced farthest from the substrate extend in generally parallel lines over at least 90% of the first power transistor.

12. The power semiconductor device of claim 10, wherein the semiconductor die further includes a second power transistor on the semiconductor substrate, and a source terminal of the second power transistor is coupled to a drain terminal of the first power transistor to form a common node.

13. The power semiconductor device of claim 12, wherein each wire of the wiring layer of the die closest to the substrate is electrically connected to a terminal of the first or second power transistor, and the wires of the wiring layer of the die spaced farthest from the substrate are electrically connected to a terminal of the first or second power transistor through each underlying wiring layer.

14. The power semiconductor device of claim 10, wherein a first one of the contact regions of the additional metal layer covers at least ¼ of the first power transistor and is electrically connected to a source terminal of the first power transistor, and wherein a second one of the contact regions of the additional metal layer covers at least % of the first power transistor and is electrically connected to a drain terminal of the first power transistor.

15. The power semiconductor device of claim 14, wherein the semiconductor die further includes a control circuit on a region of the semiconductor substrate spaced laterally apart from the first power transistor, the control circuit being operable to control operation of the first power transistor.

16. The power semiconductor device of claim 15, further comprising a plurality of thermally conductive bumps above the region of the semiconductor substrate on which the control circuit is formed, the plurality of thermally conductive bumps being electrically insulated from the control circuit and the first power transistor, laterally spaced apart from the wiring layer of the die spaced farthest from the substrate and connected to one of the contact regions of the additional metal layer for increasing heat dissipation.

17. The power semiconductor device of claim 10, wherein the wiring layer of the die spaced farthest from the substrate comprises copper and each underlying wiring layer comprises aluminum.

18. The power semiconductor device of claim 10, wherein the plurality of conductive bumps are copper pillar bumps or solder bumps and the additional metal layer forms part of a lead frame.

19. The power semiconductor device of claim 10, wherein a lateral distance between adjacent conductive vias connecting a wire of the metal layer third farthest from the substrate to a wire of the metal layer second farthest from the substrate is less than 100 μm.

20. The power semiconductor device of claim 10, wherein each wire of each wiring layer above the wiring layer closest to the substrate is electrically connected to a plurality of the wires of the immediately underlying wiring layer.

21. A power semiconductor device, comprising:
a semiconductor die with a first power transistor on a semiconductor substrate, a plurality of wiring layers vertically spaced apart from one another and the first power transistor, and a plurality of conductive bumps on each wire of the wiring layer spaced farthest from the substrate, each wire of the wiring layer closest to the substrate being electrically connected to a terminal of the first power transistor, the wires of the wiring layer spaced farthest from the substrate having a thickness of at least 4 μm, extending in generally parallel lines and being electrically connected to a terminal of the first power transistor through each underlying wiring layer; and
a lead frame including a first conductive region connected to the plurality of conductive bumps electrically connected to a source terminal of the first power transistor and a second conductive region connected to the plurality of conductive bumps electrically connected to a drain terminal of the first power transistor, the first and second conductive regions of the lead frame having a thickness of at least 50 μm.
